(19) United States
(12) Patent Application Publication
(10) Pub. No.: US 2006/0256599 A1
(43) Pub. Date: Nov. 16, 2006

(54) Database of electronically profiled cells and methods for generating and using same

(76) Inventor: Patricia J. Malin, Palo Alto, CA (US)

Correspondence Address: HELLER EHRMAN LLP, 275 MIDDLEFIELD ROAD, MENLO PARK, CA, 94025-3506, US

(21) Appl. No.: 11/386,571

(22) Filed: Mar. 21, 2006

Related U.S. Application Data
(60) Provisional application No. 60/664,663, filed on Mar. 22, 2005.

(51) Int. Cl. G11C 19/08

(52) U.S. Cl. 365/1

(57) ABSTRACT

The present invention relates to databases containing data obtained from cell cultures including conductance detected from the cultures. The invention also relates to methods of generating and using the databases.

### FIELD OF THE INVENTION

The present invention relates to databases containing data obtained from cell cultures and including conductance detected from the cultures. The invention also relates to methods of generating and using the databases.

### BACKGROUND OF THE INVENTION

Methods of cell analysis have developed rapidly in recent years. Frequently these methods include invasive technologies that result in death or mutilation of the cell sample. That is, many of these methods are plagued by problems such as the requirement of killing the cells to perform the analysis. Once the analysis is performed, the cell sample has been depleted. Thus, systems of the prior art were plagued by the inability to assay cells, analyze the cells and continue to use the cells in real time. Thus, there exists a need for a method for non-invasive analysis of cells.

Also, there is an increasingly significant problem in detecting contamination of cell cultures. This is probably no more highly publicized than by the recent announcement of the contamination of all publicly available cultures of human embryonic stem cells. Unfortunately, it was a requirement to use these cells types if a laboratory was to continue to participate in research with these cells and continue to receive federal funds. Accordingly, there exists a need for a method of detecting cell culture contamination.

Previously, cellular analyses relied on comparison of data obtained from an experimental sample with data obtained from a control sample. A frequent obstacle, however, is that the cell sample is so precious that there are not sufficient cells to perform all necessary controls each time an analysis is performed. Thus, there exists a need in the art for a method of minimizing the number of cells required to perform a variety of analyses on cells in culture. Said another way, there exists a need for a method of maximizing non-invasive analysis data.

### DESCRIPTION OF RELATED ART

U.S. Pat. No. 5,643,742 describes a system for electronically monitoring cells. U.S. Pat. Nos. 6,235,520 and 6,472,144 describe high throughput methods and apparatus for electronically monitoring cells. U.S. Pat. No. 6,656,713 describe the use of a system for electronically monitoring cells to assay cell growth or proliferation.

### SUMMARY OF THE INVENTION

The present invention provides a database comprising data representing conductance detected from a plurality, e.g. at least a first and second, cell type as measured over a period of time. In some embodiments first and second cell means first and second different cell types. However in other embodiment first and second cell means a single cell type subject to different types of treatments or conditions. Conductance is representative of or indicative of the particular cell type.

As such, the present invention also provides storage medium, particularly computer storage medium that contains the data in the database.

The invention also provides a method of profiling cells. The method includes distributing a population of cells in at least one well of a multi-well plate, and determining the conductance in the well comprising the cells, by applying a low-voltage, AC signal across a pair of electrodes placed in that well, and synchronously measuring the conductance across the electrodes, to monitor the function of cells contained in each well, whereby the conductance is representative of the type of cell type.

Given the power of the technology to profile cell types or cell metabolic states, the present invention also provides a method of identifying cell types comprising distributing cells on a substrate, detecting conductance from the cells, and comparing a representation of the detected conductance with database of conductances, whereby conductance is indicative of the cell type and the cell type is identified.

As such, the invention additionally provides a method of detecting contamination of a cell type comprising distributing cells on a substrate, detecting conductance, and comparing the detected conductance with a conductance standard for the cell type, whereby when the detected conductance is different from the conductance standard, the cell type is contaminated.

### BRIEF DESCRIPTION OF THE DRAWINGS

FIG. 1 demonstrates that cells can be monitored even after passaging cells several times.

FIG. 2 demonstrated that the device reads metabolic changes that are not only due to cell division.

FIG. 3 demonstrates the conductance plot of various cell types, e.g. fungi, bacteria and Sf9 cells.

FIG. 4 depicts conductance measured over time of SK-BR2 cells.

FIG. 5 depicts conductance of human mammary epithelial cells transfected with additional copies of the cullen oncogene.

FIG. 6 depicts the effect of chemotherapeutic agents on cellular conductance and cell number.

FIG. 7 shows the cell cycle control phases of normal cells.

FIG. 8 show the lack of cell growth phases in cancer cells.

FIG. 9 shows the derivative date for media, for comparison.

FIGS. 10A and 10B show the linear and derivative graphs for four individual wells of EPH4 cells plated at the same density.

FIGS. 11A and 11B show the linear and derivative graphs for four individual wells of BT16 cells plated at the same density.

### DETAILED DESCRIPTION OF PREFERRED EMBODIMENTS

The present invention provides a method of analyzing cells in real time over various time periods, while maintaining the ability to retrieve the cells for any additional manipulation. In addition, the present invention provides a real-time analysis of cells to detect contamination. Also, the present invention provides a database of electrical data derived from or detected from various cell types under various cell culture conditions.

The present advancement is based in part on the unappreciated realization that different cells types exhibit a unique profile when electronically monitored. It has been appreciated that cells in culture can be monitored electronically by inputting a voltage into the culture medium and assaying the conductance. However, what was not appreciated was the realization that different celtypes respond uniquely to a fixed or variable voltage and the resulting current is indicative of the particular cell type. As noted below, different cell types or identical cell types that are treated differently exhibit unique electrical properties. As such, the present invention provides a method and apparatus for profiling cell types. The present invention also provides methods of assaying for and detecting contamination of cell cultures in real time.

Accordingly, the present invention provides a database of cell conductances. That is, given that cell types display characteristic conductance patterns when exposed to a particular treatment, the present invention provides for a database of conductance data for a plurality of cell types.

By “conductance data” is meant the electrical data obtained from or detected from a sample of cells.

By “database” is meant a compilation of data. Generally, the data is representative of conductance detected from wells containing cells and or controls.

By “characteristic conductance pattern” is meant conductance that is representative of a particular cell type, cell condition such as, but not limited to cell response, cell metabolism, protein synthesis, cell mitosis, cell proliferation, cell growth, apoptosis etc.

By “wild-type” is meant a cell type that has not been manipulated relative to a cell type of similar genetic background that has been modified. Wild-type cells can include cellular explants from a patient or cells in culture.

The database includes conductance data from at least two cell types or a cell type under at least two conditions. However, preferably the database includes data from at least 5 or 10, or at least 50, 100 or 1000 to several 1000 cell types or conditions. In some embodiments the database will include cell type, cell growth conditions, cell plating density and other information related to the identification of the particular analysis.

To detect conductance, the invention relies on the electronic detection system of the prior art. As set forth in U.S. Pat. Nos. 6,472,144, 5,643,742, and 6,235,520, which are expressly incorporated herein by reference, the monitoring system includes a multiwell device The multi-well device includes plates that include but are not limited to 24-, 96-, 384-, or 1536-well plates. In addition, high-throughput systems include wells at a density of greater than about 100/cm2. In this high-throughput embodiment, the well volumes may accommodate at most about 106 cells/well, preferably between 1-100 wells/cell, and structure for measuring the conductance in each well.

The detector is configured to detect conductance from the cells. The measuring structure includes (i) a pair of electrodes adapted for insertion into a well on the substrate, and (ii) circuitry for applying a low-voltage, AC signal across the electrodes, when the electrodes are submerged in the medium. The detector system includes a pair of electrodes configured to be placed in wells of the multi well plate. In a preferred embodiment each well of the multi-well plate has a corresponding pair of electrodes configured for insertion into the well. In some embodiments, the electrode pairs are configured in the lid of the multi well plate. Such a configuration is set forth in more detail in U.S. Pat. Nos. 6,472,144, 5,643,742, and 6,235,520, which are expressly incorporated herein by reference. The electrodes detect the aggregate signal from the cells in the well. Thus, the electrodes should be close enough to the cells or cells of choice such that they can detect the signal. Without being bound by theory, it is thought that a conductivity measurement occurs when the diameter and length of the probe is more or less equal to the width between the probes. This ratio contributes to the ease with which the electric current flows through a substance.

This allows for synchronously measuring the current across the electrodes, to monitor the cell conductance as an indication of level of cellular activities such as, but not limited to growth or metabolic activity of cells contained in the well.

In various preferred embodiments, the signal circuitry is effective to generate a signal whose peak-to-peak voltage is between 5 and 10 mV, and includes feedback means for adjusting the signal voltage level to a selected peak-to-peak voltage between 5 and 10 mV.

In other embodiments, the circuitry is designed to sample the voltage of the applied signal at a selected phase angle of the signal, or alternatively, to sample the voltage of the applied signal at a frequency which is at least an order of magnitude greater than that of the signal.

Once configured, the system finds use in a variety of assays. Assays include those designed to detect responses of cells to various stimuli, detect cell types or cell metabolic state. Assays are initiated by the addition of cells to wells of the system.

Cells can include any cell type. Cell types can be either naturally occurring cells and cell populations or genetically engineered cell lines. Virtually any cell type and size can be accommodated. Cell types such as prokaryotic cells and eukaryotic cells can all be used. Also, fungi, insect cells, mammalian cells, and the like find use in the invention. In addition, any prokaryotic cells, including gram positive and negative cells find use in the invention. Cells can be homogenous cell populations and may include purified cell populations, such as cell cultures. Cell cultures may be synchronized cells or asynchronous. Cell cultures may be commercially available or publicly available cell cultures. Other cells types such as E. coli bacteria, Staphylococcus bacteria, myoblast precursors to skeletal muscle cells, neutrophil white blood cells, lymphocyte white blood cells, erythroblast red blood cells, osteoblast bone cells, chondrocyte cartilage cells, basophil white blood cells, eosinophil white blood cells, adipocyte fat cells, invertebrate neurons (Helix aspera), mammalian neurons, adrenomedullary cells, fungi, insect, algae, frog fish and plant cells may be utilized as well. In a preferred embodiment, cell types such as stem cells, including human stem cells find use in the inventions. In addition, human peripheral blood cells (HPBCs) are preferred cells for analyses. Any cell type or mixtures of cell population types may also be employed. A particularly useful source of cell lines may be found in ATCC Cell Lines and Hybridomas (8th ed., 1994), Bacteria and Bacteriophages (19 th ed., 1996), Yeast (1995), Mycology and Botany (19 th ed., 1996), and Protists: Algae and Protozoa (18 th ed., 1993), available from American Type Culture Co. (Rockville, Md.), all of which are herein incorporated by reference. Other cell repositories include the Coriell institute for Medical Research at 403 Haddon Ave., Camden, N.J. 08103.

Cells are cultured in the system according to methods known in the art. Culture conditions are well within the skill of one of ordinary skill in the art.

Once in the culture wells, the cells can be cultured in the system for a variety of incubation times. Incubation times can be from minutes to weeks, depending on the assay requirements. Generally, incubation times are from minutes or hours to weeks or days. More preferably, incubation times are less than about two weeks or more preferably less than about 10 days or 7 days. Alternatively, incubation times are more than about minutes to more than about 5 minutes to more than about 60 minutes or 120 minutes (2 hours). In addition, cells can be monitored through several passages.

Conductance can be measured at various time intervals or may be monitored continuously. That is, when it is not necessary or desired to monitor continuously, the system can be programmed to monitor at intervals ranging from every second to every 5 to 10 seconds or every 30 seconds. More preferably is every minute or every 5, 10 or 15 minutes. In some embodiments it is preferably to measure conductance at intervals of around each 30 minutes or every hour and in some embodiments it is preferable to monitor every 2 to 3, 4, 5, 6, 7, 8, 9, 10, 11, 12, 13, 14, 15, 16, 17, 18, 19, 20, 21, 22, 23, or every 24 hours, e.g. once a day. As noted previously, measurements can be obtained from incubations as short as from seconds or minutes to up to one or two to three or four weeks, depending on the viability of the cells or adequacy of the medium.

An important feature of the present invention is the ability to detect transient cellular events as they occur in a cell. That is, cells are dynamic and are undergoing a plethora of events at any given time. Cells in culture are continuously growing and modifying their environment and producing different proteins and ions over time. However, previously there had not been a method for detecting these transient events. Most cellular analyses only provide for detection of what has occurred at an end point. According to the present invention, however, methods are provided for detecting transient events as they occur. This allows for the detection of events that would otherwise not be detectable.

Importantly, the data detected from each of the analyses may be stored in a storage medium for subsequent analysis. While some analyses may be performed manually, in preferred embodiments the analysis is performed with a computer. As such the system of the invention includes storage medium, preferably computer readable storage medium and a computer. The computer is preferably running software for comparison of conductance from experimental cells or wells with conductance detected from a control well, e.g. control cells.

The computer includes a central processing unit, and system memory. Device interfaces may include both hardware components and software components. For instance, the computer may include a hard disk drive, and a floppy disk drive for reading or writing removable media. In addition, the computer may include a magneto-optical disk an optical disk drive for reading or writing optical media. The computer also may include a DVD-ROM or CD-ROM drive. The drives and their associated computer-readable media provide storage for the computer. In addition to the computer-readable media described above, other types of computer-readable media may also be used, such as ZIP drives, flash memory or the like.

A number of program modules may be stored on the drives and in the system memory. The system memory can include both Random Access Memory (“RAM”) and Read Only Memory (“ROM”). The program modules control how the computer functions and interacts with the user, with I/O devices or with other computers. Program modules include routines, operating systems, application programs, data structures, and other software or firmware components.

The computer may operate in a networked environment using logical connections to one or more remote computers. The remote computer may be a server, a router, a peer device or other common network node, and typically includes many or all of the elements described in connection with the computer. In a networked environment, program modules and data may be stored on the remote computer.

As a result of storing the data from various experiments in the computer or on storage medium, the system allows for the creation and utilization of a database of electrical information from cell types and cell conditions. One particular advantage of the current system is that for the first time it has been appreciated that different cell types or cells under different conditions exhibit reproducible and characteristic electrical data. That is, different cell types exhibit unique electrical data as measured by the system of the invention. In addition, cell types under different conditions exhibit characteristic electrical responses in the system. Accordingly, the system provides a database of electrical data of different cell types and different culture conditions.

Having stored data from various cellular and control analyses, comparisons can be performed with data from subsequent experimental sessions. As such, in subsequent sessions, the data can be compared with either or both, internal controls, e.g. controls in the sample plate, and stored data. Comparisons are facilitated by performing various data manipulations or plotting graphs and comparing the data or graphs. Preferably, the background signal is subtracted from the experimental signal. Also, it is preferably to plot conductance as a function of time as demonstrated in the figures.

An individual well may be plotted. Media can be subtracted from an individual cell well. The plot of an individual well may also be normalized.

In addition, various other statistical analyses can be performed with the data. For example. The system also averages the data points taken for each well during each run to arrive at a single reading, X. The readings for all wells in each group are then averaged to obtain a group average, Xij, for each run. An example is illustrative:

Group 1 comprises wells C2, D2, and A3

For each run,

$$X 2 = \frac{[ {X}_{C 2} + {X}_{D 2} + {X}_{A 3} ]}{3}$$

The normalized group average, N, for each group for each run is obtained by the following calculation:
N=Xₜ−X₀
where Xₜ=Group average for the run
and X₀=Group average at initial (time 0) reading

The corrected group average, C, for each group for each run is obtained by the following calculation:
C=Nₜ−Nₘ
where Nₜ=Normalized group average for the current run
and Nₘ=Normalized group average of the media control group for current run

In some embodiments, a derivative graph or plot is used. The derivative is the growth rate of the cell population. By subtracting the preceding number from the current number the growth rate is obtained
growth rate=current data point−last data point
Xₙ=Xₙ−Xₙ₋₁
This representation shows the changes in the growth rate over time and allows for the profiling of the cells.

In some embodiments, variance graphs or plots are used. Variance graphs represent the Total Average Variance for each Run in a Cell Group.

$$Variance , Var ( x ) = \frac{1}{n} \sum {( {x}_{i} - \overline{x} )}^{2}$$

Where, xᵢ=The Well Average of the Cell Group for each Run
n=Total Number of Runs

In some embodiments a correlation graph or plot is used. Correlation graph represents the Correlation between two Cell Groups.

$$Correlation , r = \frac{\sum ( {x}_{i} - \overline{x} ) ( {y}_{i} - \overline{y} )}{\sqrt{Var ( x ) Var ( y )}}$$

Where, xᵢ=The Average of 1^{st} Cell Group's Well Average for each Run
yᵢ=The Average of 2^{nd} Cell Group's Well Average for each Run

The standard plot is the total number of cells vs time.

The derivative is the growth rate, which is the derivative of the first plot.

In a preferred embodiment, when calculating variance, one has different measurements, under the same conditions, of cells vs time. The variance depicts the variability in the cell counts over time, or in the growth rate over time and add confidence intervals to that plot.

The correlation plot correlates the data from the system to a cell number. In some embodiments the system also includes a cell calculator or cell counter. Thus, one can manually count cells and input cell count into the system or the cell counting can be automated with the cell counter or cell calculator. The data from the cell counter or calculator is input into the system for analysis and comparison with conductance data or other data.

Once implemented, the system finds use in detecting a variety of cellular parameters. Such parameters include detecting various metabolic states of the cells. In addition, the assays can detect cell types. Also, the system can detect cellular contamination.

By detecting various metabolic states is meant that the system can detect when cells in a culture are in a particular cellular phase, such as proliferating, dieing, growing and the like. For example, proliferating cells of a particular cell type display characteristic conductance with respect to time and can be distinguished from, for example, senescent cells of the same cell type. Likewise, cells growing in size can be detected when compared to non-growing cells, an effect that is not readily detected based on cell count or other cell proliferation markers. Other characteristic that are detected in the system include, but are not limited to cell metabolism, cell growth, cell division, apoptosis, protein synthesis, cell death, cell size, and the like.

As noted previously, the system of the invention also provides a method for detecting contamination of cell cultures. By “contaminated” is meant that the cells are impure as a result of their exposure to a foreign substance. The foreign substance can be a living organism, such as fungus, bacteria, or virus. Alternatively, foreign substance need not be a living organism, but can be a chemical or foreign molecule. The foreign substance could be an unwanted growth factor, chemical entity, carbohydrate, lipopolysaccharide, and the like.

In this embodiment, conductance from cells in a particular well, can be compared with either a control well or cells in a control sample plate. Cells that are contaminated display characteristic conductance with respect to time and can be distinguished from uncontaminated cells. Importantly, conductance from cells in a sample well also can be compared to reference data of the same cell type. As noted previously, conductance data is stored or archived and can be accessed for comparison to newly derived data. A conductance profile from the recently derived data that is different from the archived data from control cells, provides an indication that the cells are contaminated.

In addition, the method finds use in detecting modified cells. By “modified cells” is meant a cell that is changed with respect to the wild-type cell. A modified cell may be a contaminated cell. Alternatively, a modified cell may be a cell that is transfected, infected, or transformed, etc. by a modifying agent. By “modifying agent” is meant an agent that modifies a cell and can include a infectious agents or nucleic acids and the like. By “nucleic acid” or “oligonucleotide” or grammatical equivalents herein means at least two nucleotides covalently linked together. A nucleic acid of the present invention will generally contain phosphodiester bonds, although in some cases, as outlined below, nucleic acid analogs are included that may have alternate backbones, comprising, for example, phosphoramide (Beaucage, et al., Tetrahedron, 49(10):1925 (1993) and references therein; Letsinger, J. Org. Chem., 35:3800 (1970); Sprinzl, et al., Eur. J. Biochem., 81:579 (1977); Letsinger, et al. Nucl. Acids Res., 14:3487 (1986); Sawai, et al., Chem. Lett., 805 (1984), Letsinger, et al., J. Am. Chem. Soc., 110:4470 (1988); and Pauwels, et al., Chemica Scripta, 26:141 (1986)), phosphorothioate (Mag, et al., Nucleic Acids Res., 19:1437 (1991); and U.S. Pat. No. 5,644,048), phosphorodithioate (Briu, et al., J. Am. Chem. Soc., 111:2321 (1989)), O-methylphophoroamidite linkages (see Eckstein, Oligonucleotides and Analogues: A Practical Approach, Oxford University Press), and peptide nucleic acid backbones and linkages (see Egholm, J. Am. Chem. Soc., 114:1895 (1992); Meier, et al., Chem. Int. Ed. Engl., 31:1008 (1992); Nielsen, Nature, 365:566 (1993); Carlsson, et al., Nature, 380:207 (1996), all of which are incorporated by reference)). Other analog nucleic acids include those with positive backbones (Denpcy, et al., Proc. Natl. Acad. Sci. USA., 92:6097 (1995)); non-ionic backbones (U.S. Pat. Nos. 5,386,023; 5,637,684; 5,602,240; 5,216,141; and 4,469,863; Kiedrowshi, et al., Angew. Chem. Intl. Ed. English, 30:423 (1991); Letsinger, et al., J. Am. Chem. Soc., 110:4470 (1988); Letsinger, et al., Nucleosides & Nucleotides, 13:1597 (1994); Chapters 2 and 3, ASC Symposium Series 580, “Carbohydrate Modifications in Antisense Research”, Ed. Y. S. Sanghui and P. Dan Cook; Mesmaeker, et al., Bioorganic & Medicinal Chem. Lett., 4:395 (1994); Jeffs, et al., J. Biomolecular NMR, 34:17 (1994); Tetrahedron Lett., 37:743 (1996)) and non-ribose backbones, including those described in U.S. Pat. Nos. 5,235,033 and 5,034,506, and Chapters 6 and 7, ASC Symposium Series 580, “Carbohydrate Modifications in Antisense Research”, Ed. Y. S. Sanghui and P. Dan Cook. Nucleic acids containing one or more carbocyclic sugars are also included within the definition of nucleic acids (see Jenkins, et al., Chem. Soc. Rev., (1995) pp. 169-176). Several nucleic acid analogs are described in Rawls, C & E News, Jun. 2, 1997, page 35. All of these references are hereby expressly incorporated by reference. These modifications of the ribose-phosphate backbone may be done to facilitate the addition of additional moieties such as labels, or to increase the stability and half-life of such molecules in physiological environments; for example, PNA is particularly preferred. In addition, mixtures of naturally occurring nucleic acids and analogs can be made. In a particularly preferred embodiment the modifying agent is an siRNA or antisense RNA.

Modifying agent also may be an exogenous gene or cDNA. The gene or cDNA may be under the control of and/or operably linked to a promoter to drive the expression of the mRNA and protein encoded by the cDNA or protein. By “exogenous” is meant that the nucleic acid, e.g. the gene or cDNA, is added to the cell. While the exogenous gene may have the same sequence as an endogenous gene, it is still considered exogenous because it is added to the cell. As such, the invention provides for a method of detecting the timing of expression of genes. While the gene need not be an exogenous gene or cDNA, for the purposes of identifying the timing of expression of a particular gene, the identify of the gene to be monitored should be known. That is, while it is possible to detect a change electrical activity of a cell or cell culture and this may correlate with altered expression of endogenous genes, it is not possible to identify which endogenous gene caused the change in cellular conductance. However, when the gene (or cDNA) is an exogenous gene, the correlation between expression and altered cellular conductance is more readily identified. This is particularly true when the exogenous nucleic acid is under the control of an inducible promoter. Inducible promoters are varied and readily available from a variety of sources. The skilled artisan will understand the requirements of preparing the exogenous nucleic acid including a promoter, in particular an inducible promoter.

Alternatively, mixtures of different nucleic acid analogs, and mixtures of naturally occurring nucleic acids and analogs may be made. The nucleic acids may be single stranded or double stranded, as specified, or contain portions of both double stranded or single stranded sequence. The nucleic acid may be DNA, both genomic and cDNA, RNA or a hybrid, where the nucleic acid contains any combination of deoxyribo- and ribo-nucleotides, and any combination of bases, including uracil, adenine, thymine, cytosine, guanine, inosine, xanthine, hypoxanthine, isocytosine, isoguanine, and base analogs such as nitropyrrole and nitroindole, etc.

Accordingly, the invention provides a method of profiling cells. In the method cells from a population of cells are distributed in a culture well with the requisite medium and cultured for the desired amount of time. Conductance is detected as outlined above at various time intervals as frequent as seconds to minutes to hours. As noted previously, detection can continue for up to weeks, but may last as short as from minutes to hours or days. Alternatively, conductance can be measured continuously

In a preferred embodiment the method also provides for simultaneous analysis of a variety of cell types. As such, the method includes distributing a first sample from a first population of cells in a well and distributing a first sample from a second population of cells in a well of an assay plate. In this example, each population is a different cell type, or a similar cell type that has undergone different treatments prior to the analysis. Again, the cells are cultured and conductance is detected over a period of time. Conductance data is stored and analyzed.

Alternatively, conductance data is compared in real time. By in real time is meant that as the analysis is performed, the conductance data is measured and compared to either data from another well, or to data stored, for example in a database.

In addition, the method finds use in identifying cell types. In this embodiment a sample of cells, the identity of which is unknown, is distributed in a sample well as described above. Conductance of the cells is detected and compared with a conductance data from the database described above. In some embodiments, the crude data is compared to the crude data in the database. Alternatively, a representation of the data is prepared and compared with a representation, such as a graph, of the data from the database.

The invention also provides a method of identifying the effect of a bioactive agent on a cell. In the method, cells are distributed in the assay well as noted previously. Cells are contacted with a bioactive agent. By “bioactive agent” is meant as used herein describes any molecule, e.g., protein, oligopeptide, small organic molecule, coordination complex, polysaccharide, polynucleotide, etc. which can be contacted with the cells in the assay of the invention.

Bioactive agents encompass numerous chemical classes, though typically they are organic molecules, preferably small organic compounds having a molecular weight of more than 100 and less than about 2,500 Daltons. Bioactive agents comprise functional groups necessary for structural interaction with proteins, particularly hydrogen bonding, and typically include at least an amine, carbonyl, hydroxyl or carboxyl group, preferably at least two of the functional chemical groups. The bioactive agents often comprise cyclical carbon or heterocyclic structures and/or aromatic or polyaromatic structures substituted with one or more of the above functional groups. Bioactive agents are also found among biomolecules including peptides, nucleic acids, saccharides, fatty acids, steroids, purines, pyrimidines, derivatives, structural analogs or combinations thereof. Particularly preferred are nucleic acids and proteins.

Bioactive agents can be obtained from a wide variety of sources including libraries of synthetic or natural compounds. For example, numerous means are available for random and directed synthesis of a wide variety of organic compounds and biomolecules, including expression of randomized oligonucleotides. Alternatively, libraries of natural compounds in the form of bacterial, fungal, plant and animal extracts are available or readily produced. Additionally, natural or synthetically produced libraries and compounds are readily modified through conventional chemical, physical and biochemical means. Known pharmacological agents may be subjected to directed or random chemical modifications, such as acylation, alkylation, esterification and/or amidification to produce structural analogs.

In a preferred embodiment, the bioactive agents are proteins. By “protein” herein is meant at least two covalently attached amino acids, which includes proteins, polypeptides, oligopeptides and peptides. The protein may be made up of naturally occurring amino acids and peptide bonds, or synthetic peptidomimetic structures. Thus “amino acid”, or “peptide residue”, as used herein means both naturally occurring and synthetic amino acids. For example, homo-phenylalanine, citrulline and norleucine are considered amino acids for the purposes of the invention. The side chains may be in either the (R) or the (S) configuration. In the preferred embodiment, the amino acids are in the (S) or L-configuration. If non-naturally occurring side chains are used, non-amino acid substituents may be used, for example to prevent or retard in vivo degradations.

In one preferred embodiment, the bioactive agents are naturally occurring proteins or fragments of naturally occurring proteins. Thus, for example, cellular extracts containing proteins, or random or directed digests of proteinaceous cellular extracts, may be used. In this way libraries of prokaryotic and eukaryotic proteins may be made for screening in the systems described herein. Particularly preferred in this embodiment are libraries of bacterial, fungal, viral, and mammalian proteins, with the latter being preferred, and human proteins being especially preferred.

In a preferred embodiment, the bioactive agents are peptides of from about 5 to about 30 amino acids, with from about 5 to about 20 amino acids being preferred, and from about 7 to about 15 being particularly preferred. The peptides may be digests of naturally occurring proteins as is outlined above, random peptides, or “biased” random peptides. By “randomized” or grammatical equivalents herein is meant that each nucleic acid and peptide consists of essentially random nucleotides and amino acids, respectively. Since generally these random peptides (or nucleic acids, discussed below) are chemically synthesized, they may incorporate any nucleotide or amino acid at any position. The synthetic process can be designed to generate randomized proteins or nucleic acids, to allow the formation of all or most of the possible combinations over the length of the sequence, thus forming a library of randomized bioactive proteinaceous agents.

In a preferred embodiment, a library of bioactive agents are used. In a preferred embodiment, the library is fully randomized, with no sequence preferences or constants at any position. In a preferred embodiment, the library is biased. That is, some positions within the sequence are either held constant, or are selected from a limited number of possibilities. For example, in a preferred embodiment, the nucleotides or amino acid residues are randomized within a defined class, for example, of hydrophobic amino acids, hydrophilic residues, sterically biased (either small or large) residues, towards the creation of cysteines, for cross-linking, prolines for SH-3 domains, serines, threonines, tyrosines or histidines for phosphorylation sites, etc., or to purines, etc.

In a preferred embodiment, the bioactive agents are nucleic acids as described herein.

Upon treatment with a bioactive agent or following treatment with a bioactive agent, conductance is measured or detected and analyzed. As noted previously, conductance can be compared to a control, e.g. a control sample well on the same plate, where a difference in conductance between the treated well and the control indicates that the bioactive agent had an effect on the cell. Alternatively, conductance is measured or detected and compared to a database as described herein. This method allows for detecting not only a change in conductance with respect to a control, but also provides a method for determining what type of an effect the bioactive agent had on the cell or cells. This is because the database includes conductance data for different cell types with different treatments and in cells undergoing different metabolic states. Thus, observing a characteristic change in conductance of a cell or cells provides and indication that the bioactive agent affected a particular cell function or characteristic. Such information will rapidly facilitate therapeutic development and provides a method for rapidly screening various bioactive agents or candidate therapeutic molecules. The power of the method lies not only in detecting that the bioactive agent affected the cell, but in determining what cellular function was affected.

The following examples serve to more fully describe the manner of using the above-described invention, as well as to set forth the best modes contemplated for carrying out various aspects of the invention. It is understood that these examples in no way serve to limit the true scope of this invention, but rather are presented for illustrative purposes. All references cited herein are incorporated by reference in their entirety.

### EXAMPLES

### Example 1

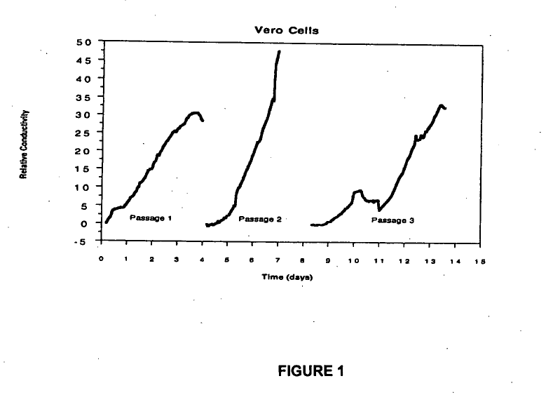

FIG. 1 demonstrates that cells can be monitored even after passaging cells several times.

Serum-free media was developed that would support the growth of Vero cells. The media was then tested to ensure that the growth rate would be approximately the same for three sequential passages. Cells were grown and monitored for 4 days. split and sub cultured for an additional four days. The process was repeated again. Conductance was measured for the entire duration of 14 days and demonstrates that the Vero cells maintained approximately the same growth rate.

### Example 2

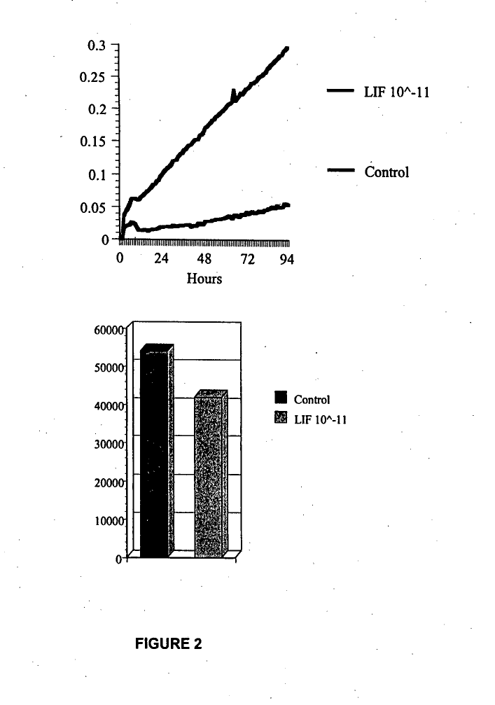

FIG. 2 demonstrates the response of rat primary neonatal explants. Seeding density was 5×10³ in 1 ml of media. The CellStat™ cell analysis system is capable of measuring metabolic responses that are not caused by cell division since one of the main characteristic of these cells in their inability to divide under given conditions.

It has been shown in a separate paper “Phenylephrine, endothelin, prostaglandin F2alpha’ and leukemia inhibitory factor induce different cardiac hypertrophy phenotypes in vitro King K L, Winer J, Phillips D M, Quach J, Williams P M, Mather J P Genentech, Inc., South San Francisco, Calif. 94080, USA. that the metabolic activity with these ligands increased as follows: PGF increased by 54%; Heart beats PE increased by 84% Heart beats with LIF increased by 125%

### Example 3

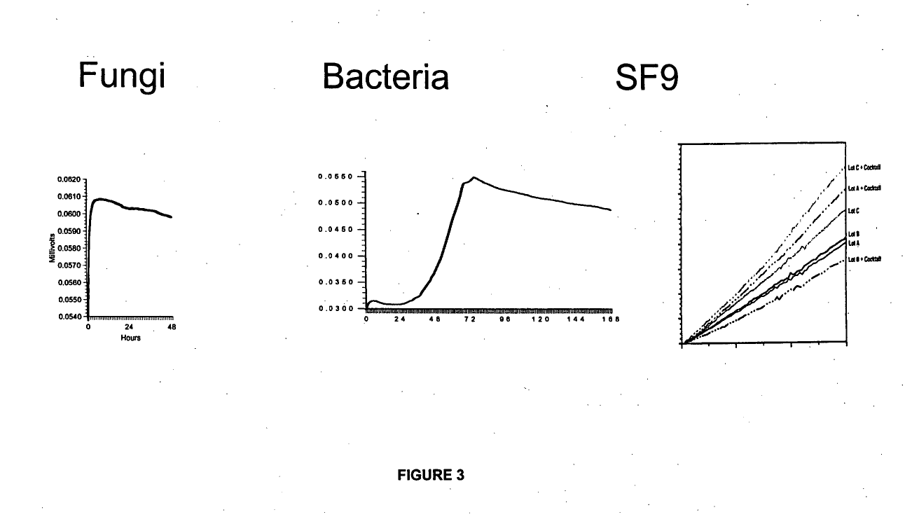

FIG. 3 demonstrates the conductance plot of various cell types, e.g. fungi, bacteria and Sf9 cells.

Note the distinct conductance plots. These data demonstrate that conductance plots for different cell types are characteristic or representative of the cell type.

### Example 4

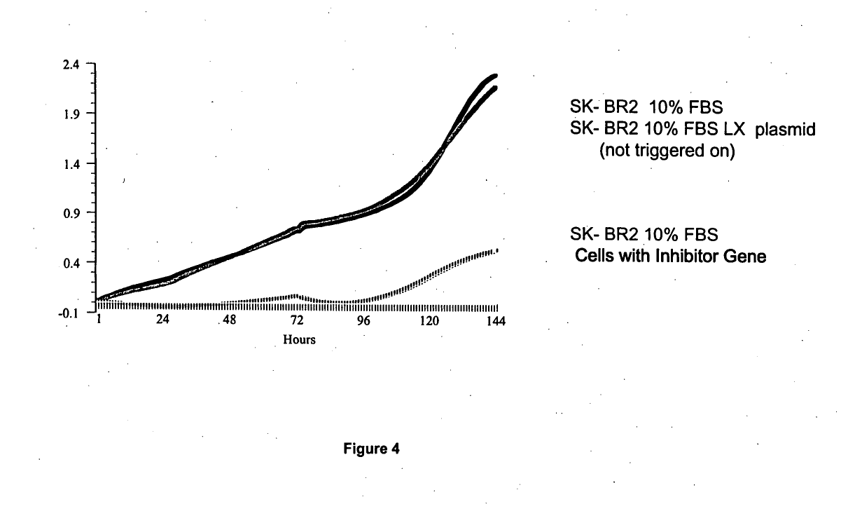

FIG. 4 depicts conductance measured over time of SK-BR2 cells.

Cells were plated in 2 ml of media at an initial seeding density of 2.0×10⁴. Cells were cultured under control conditions, conditions including the LX plasmid (not triggered on) or conditions under which the plasmid is “triggered on” and the gene is induced. The gene is the Th and is known to inhibit mitochondrial function and therefore cellular respiration and metabolism. These data demonstrate that induction of the Th gene reduces conductance, an indication of reduced metabolic activity. Again, such a result would not be observable by visualizing the cells or counting the cells.

### Example 5

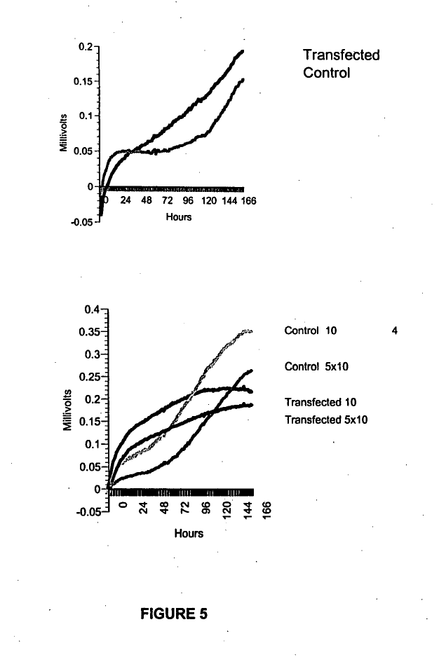

FIG. 5 depicts conductance of human mammary epithelial cells transfected with additional copies of the cullen oncogene.

As shown in FIG. 5, the cullen oncogene induced and early increase in conductance, which was consistent with observed increase in cell size.

Human mammary epithelial cells were transfected with additional copies of a candidate oncogene. The purpose was to see whether overexpression of the gene would effect proliferation of the cell line. The CellStat™ cell analyzer readings were consistent with previous observations that the transfected cells initially grow more rapidly than the control while also growing larger in size, and then their growth tapers as the immortalized control cells begin proliferating at an increased rate.

### Example 6

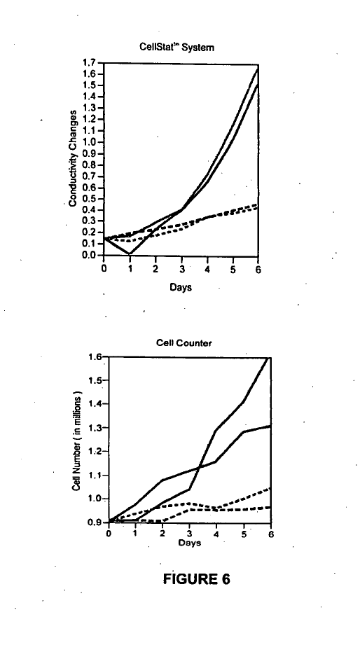

FIG. 6 depicts the effect of chemotherapeutic agents on cellular conductance and cell number.

As shown in FIG. 6, treatment of cells in culture induced a decrease in cell conductance that correlated well with decreased cell number. Cells were seeding at a density of 1.0E+5 in 2 ml of DMEM with 10% FBS. The cells were grown and cultured for 24 hours. On day 2 eight wells were counted in a Coulter type counter after harvesting by trypsinization for initial cell count. Additional wells containing cells were examined to confirm cell viability and health by phase microscopy. The media as then aspirated and wells were filled with DMEM+10% serum (control) or DMEM+10% serum containing various concentrations of chemotherapeutic agent (e.g. Methotrexate.). The dose was 100 ng in each ml of media.

### Example 7

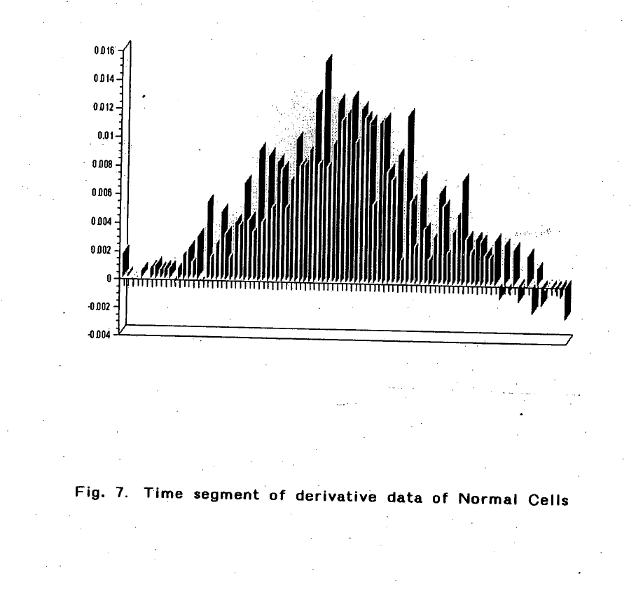

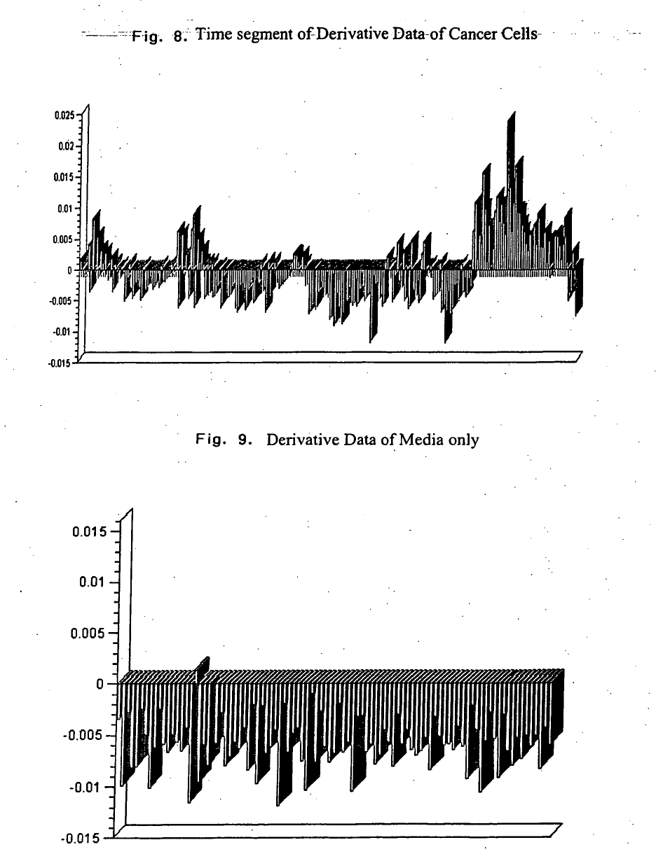

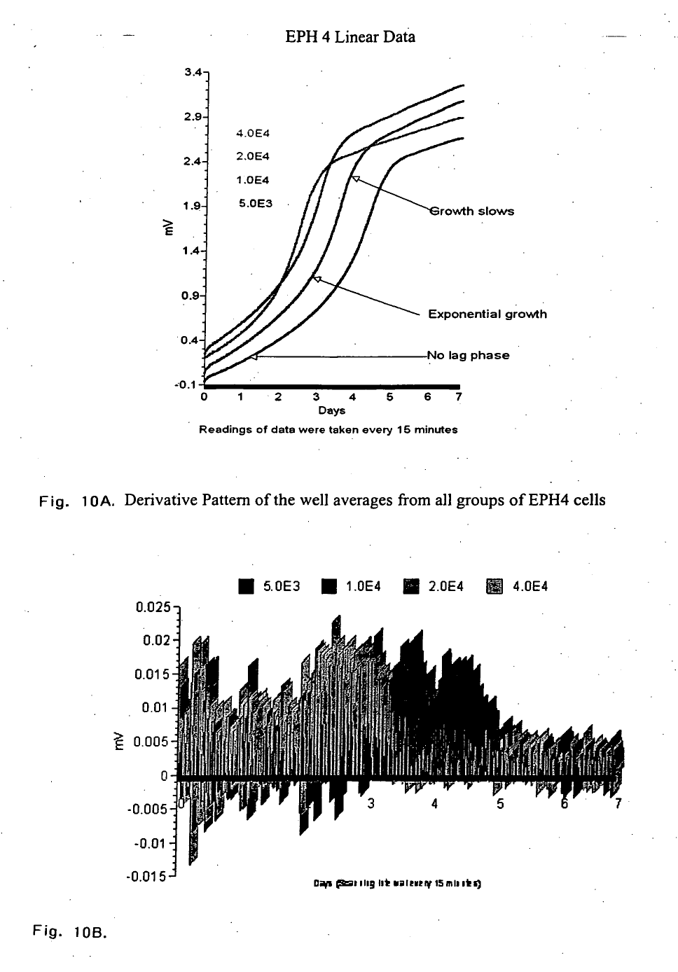

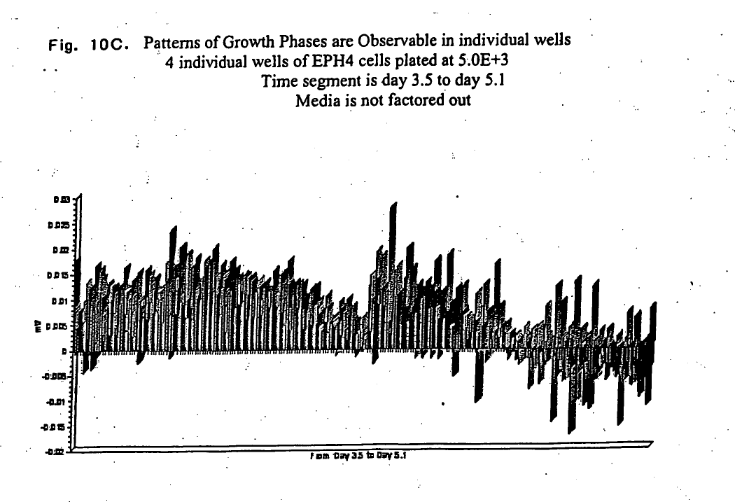

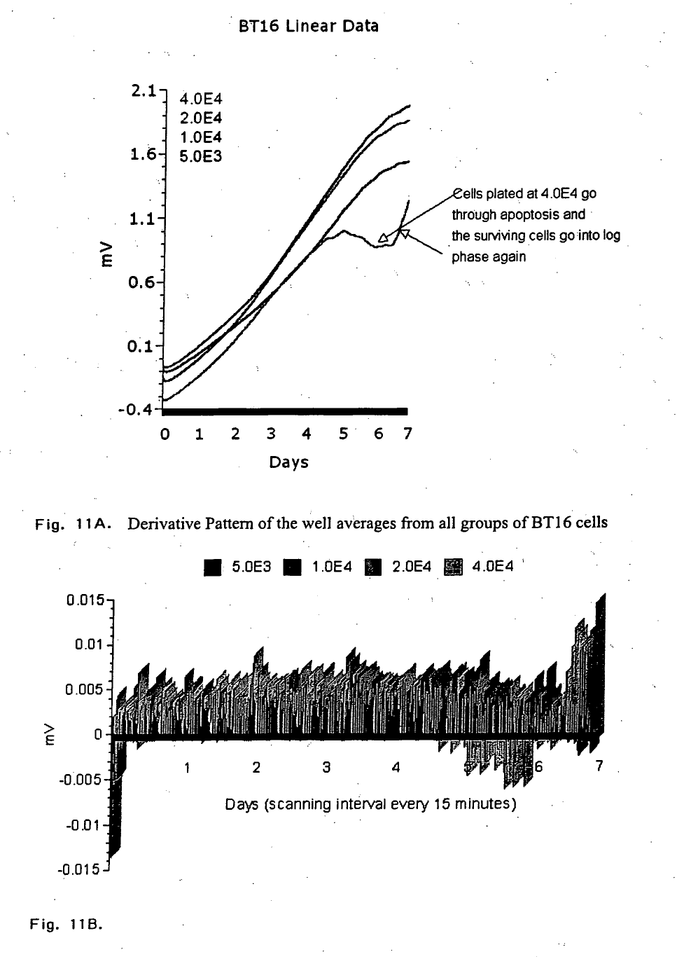

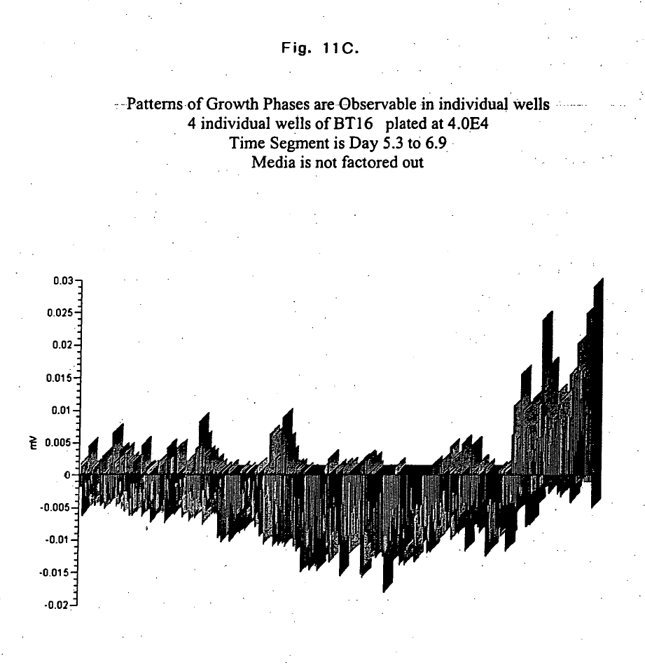

FIGS. 7-11 illustrate that changes in cell phases are readily observable using the method of the present invention. Cells entering long or plateau phase can be observed as they occur in the living culture. FIG. 7 shows the cell cycle control phases of normal cells tested in accordance with the present invention. FIG. 8 shows the lack of cell growth phases in cancer cells. FIG. 9 shows the derivative data for media, for comparison purposes. The sampling rate was every 15 minutes. FIGS. 10A and 10B show the linear and derivative graphs for four wells of EPH4 cells plated at the same density. The graphs show that these cells proliferate and when they reach confluency, they reduce their confluency but still continue to grow. FIGS. 11A and 11B show the linear and derivative graphs for four individual wells of BT16 cells plated at the same density. The linear graph shows that this very aggressive melanoma cell line plated at 40K becomes apoptose and then starts growing again. FIGS. 10A and B and 11A and B illustrate that the characteristic patterns can be observed even in individual wells plated at the same density, and without factoring out the media.

1. A database comprising:
data representing conductance detected from at least a first and second cell type as measured over a period of time.

2. The database according to claim 1, wherein said conductance is detected from a plurality of cells of said first and second cell types.

3. The database according to claim 1, wherein said conductance is detected from at least 5 cell types.

4. The database according to claim 1, wherein said data representing conductance from each cell type is representative of said cell type.

5. The database according to claims 1-4, wherein said period of time is at least about 5 minutes.

6. The database according to claims 1-4, wherein said period of time is less than 14 days

7. The database according to claims 1-4, wherein said period of time is between about 5 minutes and about 14 days.

8. The database according to claim 7, wherein said period of time is between about 1 hour and 10 days.

9. The database according to claims 1, wherein said conductance is measured by a pair of electrodes.

10. Storage medium comprising the database according to claim 1.

11. The storage medium according to claim 10, wherein said storage medium is computer readable.

12. The storage medium according to claim 11, wherein said storage medium is selected from the group consisting of hard disk, magneto-optical disk, etc.

13. A computer comprising the storage medium according to claim 10, 11 or 12.

14. A method of profiling cells comprising:
a) distributing a population of cells in at least one well of a multi-well plate;
b) determining the conductance in said well comprising said cells, by applying a low-voltage, AC signal across a pair of electrodes placed in that well, and synchronously measuring the conductance across the electrodes, to monitor the function of cells contained in each well, whereby said conductance is representative of the type of cell in said population.

15. The method according to claim 14, further comprising comparing said conductance with a database of measured conductances to identify said type of cell.

16. The method according to claim 14, whereby said distributing comprises:
a) distributing cells from the same population into two different wells of said multi-well plate.

17. The method according to claim 16, wherein cells in a first of said two different wells are contacted with an agent and cells in a second of said two different wells are contacted with a control for said agent, whereby a difference in conductance measured in said first well relative to the conductance measured in said second well is indicative of said agent having an effect on a function of said cells of said first population.

18. The method according to claim 17, wherein said function is selected from the group consisting of cell growth, cell metabolism, mitosis, meiosis, protein synthesis, cell division, cell death, or cell size.

19. The method according to claim 14-18, wherein said cells are selected from the group consisting of prokaryotic and eukaryotic cells.

20. The method according to claim 14, wherein each well comprises at least one cell.

21. The method according to claim 14, wherein said multi-well plate comprises at least 2 wells.

22. The method according to claim 14, wherein said multi-well plate comprises at least 6 wells.

23. The method according to claim 14, wherein said multi-well plate comprises at least 24 wells.

24. The method according to claim 14, wherein said multi-well plate comprises at least 96 wells.

25. The method according to claim 14, wherein said multi-well plate comprises at least 384 wells.

26. The method according to claim 14, wherein said multi-well plate comprises at least 1536 wells.

27. The method according to claim 14, wherein said agent is selected from the group consisting of polypeptides, small molecules and nucleic acids.

28. A method of identifying cell types comprising:
a) distributing cells on a substrate;
b) detecting conductance from said cells;
c) comparing a representation of said detected conductance with database of conductances, whereby conductance is indicative of said cell type and said cell type is identified

29. A method of detecting contamination of a cell type comprising:
a) distributing cells on a substrate;
b) detecting conductance;
c) comparing the detected conductance with a conductance standard for said cell type, whereby when said detected conductance is different from said conductance standard, said cell type is contaminated.

30. The method according to claim 29, wherein said cell type is contaminated with a contaminant selected from the group consisting of nucleic acid, virus, bacteria, fungi or lipopolysaccharide.
